(19) United States
(12) Patent Application Publication
(10) Pub. No.: US 2015/0348621 A1
(43) Pub. Date: Dec. 3, 2015

(54) NONVOLATILE SEMICONDUCTOR MEMORY DEVICE AND READ METHOD THEREOF

(71) Applicant: KABUSHIKI KAISHA TOSHIBA, Minato-ku (JP)

(72) Inventor: Mario SAKO, Yokohama (JP)

(73) Assignee: KABUSHIKI KAISHA TOSHIBA, Minato-ku (JP)

(21) Appl. No.: 14/825,762

(22) Filed: Aug. 13, 2015

Related U.S. Application Data
(63) Continuation of application No. PCT/JP2013/073726, filed on Aug. 28, 2013.

(30) Foreign Application Priority Data
Mar. 8, 2013 (JP) 2013-046478
Jul. 26, 2013 (JP) 2013-155252

(51) Int. Cl. G11C 11/56

(52) U.S. Cl. CPC G11C 11/5642

(57) ABSTRACT

This nonvolatile semiconductor memory device comprises a memory cell array configured having a plurality of NAND cell units arranged therein, each of the NAND cell units being configured having a plurality of memory cells connected in series therein. A bit line is connected to one end of the NAND cell unit, and a source line is connected to the other end of the NAND cell unit. A sense amplifier circuit is connected to the bit line. The sense amplifier circuit comprises: a first switch circuit connected between a power supply voltage terminal and a sense node; a sense amplifier connected to the sense node; and a latch circuit that latches a signal outputted from the sense amplifier. The first switch circuit is configured to switch to a non-conductive state according to data latched by the latch circuit.

### CROSS REFERENCE TO RELATED APPLICATIONS

This application is based upon and claims the benefit of priority from prior Japanese Patent Application No. 2013-46478, filed on Mar. 25, 2013, and prior Japanese Patent Application No. 2013-155252, filed on Jul. 26, 2013, the entire contents of which are incorporated herein by reference.

### FIELD

Embodiments described in the present specification relate to a nonvolatile semiconductor memory device and a read method thereof.

### BACKGROUND

A NAND type flash memory is known as a nonvolatile semiconductor memory device that is electrically rewritable and capable of a high degree of integration. In a NAND type flash memory, a plurality of memory cells are connected in series in a form where memory cells adjacent to each other share a source/drain diffusion layer, thereby configuring a NAND cell unit. A bit line and a source line are respectively connected to both ends of the NAND cell unit via select gate transistors.

In such a NAND type flash memory, a multi-level storage system that stores two or more bits of data in one memory cell is employed for the purpose of increasing storage capacity. In the case where this multi-level storage system (MLC) is employed, in order to read data from one memory cell, a plurality of word line voltages having values that differ from each other are applied to perform a plurality of times of read operations in one memory cell.

Moreover, even in the case where a single-level storage system (SLC) that stores only one bit of data in one memory cell is employed, a plurality of times of read operations are sometimes performed in one memory cell.

In the case where such a plurality of times of read operations are performed, each time, the bit line is charged to a certain potential. This charging operation is a cause of an increase in power consumption of the NAND type flash memory.

### BRIEF DESCRIPTION OF THE DRAWINGS

FIG. 1A is a block diagram showing a configuration of a nonvolatile semiconductor memory device according to a first embodiment.

FIG. 1B is an equivalent circuit diagram showing the configuration of the nonvolatile semiconductor memory device in the first embodiment.

FIG. 1C is a schematic view showing a cross-sectional structure of a memory cell MC.

FIG. 1D is a schematic view showing cross-sectional structure of select transistors SG1 and SG2.

FIG. 1E is a schematic view showing a cross-sectional structure of a NAND cell unit NU.

FIG. 2 is a schematic view explaining a multi-level storage system in a NAND type flash memory.

FIG. 3 is a schematic view explaining the multi-level storage system in the NAND type flash memory.

FIG. 4 is a schematic view explaining the multi-level storage system in the NAND type flash memory.

FIG. 5 is a block diagram showing a specific example of configuration of a sense amplifier circuit 112 in the nonvolatile semiconductor memory device of the first embodiment.

FIG. 6 is a flowchart explaining a read operation in the nonvolatile semiconductor memory device of the first embodiment.

FIG. 7 is a block diagram showing a specific example of configuration of a sense amplifier circuit 112 in a nonvolatile semiconductor memory device of a second embodiment.

FIG. 8 is a flowchart explaining a read operation in the nonvolatile semiconductor memory device of the second embodiment.

### DETAILED DESCRIPTION

A nonvolatile semiconductor memory device in an embodiment described below comprises a memory cell array configured having a plurality of NAND cell units arranged therein, each of the NAND cell units being configured having a plurality of memory cells connected in series therein. A bit line is connected to one end of the NAND cell unit, and a source line is connected to the other end of the NAND cell unit. A sense amplifier circuit is connected to the bit line. The sense amplifier circuit comprises: a first switch circuit connected between a power supply voltage terminal and a sense node; a sense amplifier connected to the sense node; and a latch circuit that latches a signal outputted from the sense amplifier. The first switch circuit is configured to switch to a non-conductive state according to data latched by the latch circuit.

Next, a nonvolatile semiconductor memory device according to embodiments is described based on the drawings.

### First Embodiment

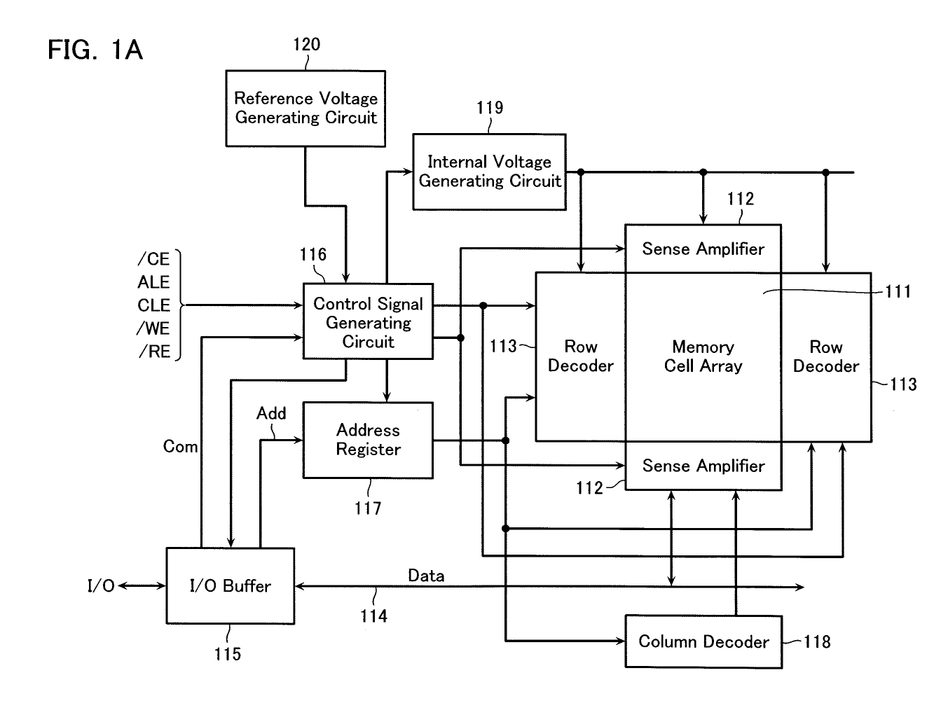

First, a configuration of a nonvolatile semiconductor memory device according to a first embodiment will be described with reference to FIGS. 1A and 1B. FIG. 1A is a block diagram showing the configuration of the nonvolatile semiconductor memory device (NAND type flash memory) according to the first embodiment. FIG. 1B is an equivalent circuit diagram showing a configuration of a memory cell array 111. Note that in FIG. 1B, a direction in which a word line WL extends is referred to as a word line direction, and a direction in which a bit line BL extends is referred to as a bit line direction.

As shown in FIG. 1A, the nonvolatile semiconductor memory device according to the first embodiment includes the memory cell array 111, a sense amplifier 112, a row decoder 113, a data line 114, an I/O buffer 115, a control signal generating circuit 116, an address register 117, a column decoder 118, an internal voltage generating circuit 119, and a reference voltage generating circuit 120.

As shown in FIG. 1B, the memory cell array 111 is configured having a plurality of NAND cell units NU arranged in a matrix therein. Each NAND cell unit NU includes, for example, 64 series-connected electrically rewritable nonvolatile memory cells MC0˜MC63 (a memory string) and select transistors SG1 and SG2 for respectively connecting both ends of that memory string to the bit line BL and a common source line CELSRC.

Control gates of the memory cells MC0˜MC63 in the NAND cell unit NU are connected to different word lines WL0˜WL63. Gates of the select transistors SG1 and SG2 are respectively connected to select gate lines SGD and SGS. A group of NAND cell units NU sharing one word line WL configures a block BLK which forms a unit of data erase. Although omitted from the drawings, a plurality of the blocks BLK are arranged in the bit line direction.

Each bit line BL is connected to the sense amplifier 112 shown in FIG. 1A. The plurality of memory cells MC commonly connected to one word line WL configure one page or multiple pages.

As shown in FIG. 1A, the sense amplifier 112 is disposed in the bit line direction of the memory cell array 111 and as well as being connected to the bit line BL to perform read of a page unit of data, and also serves as a data latch that holds one page of write data. That is, read and write are performed in units of the page. The sense amplifier 112 is provided with a data cache that temporarily holds input/output data and a column select gate circuit that performs column selection (not illustrated).

As shown in FIG. 1A, the row decoder 113 is disposed in the word line direction of the memory cell array 111 and selectively drives the word line WL and the select gate lines SGD and SGS according to a row address. This row decoder 113 includes a word line driver and a select gate line driver. In addition, the column decoder 118 that controls the column select gate circuit in the sense amplifier 112 is provided accompanying the sense amplifier 112. The row decoder 113, the column decoder 118, and the sense amplifier 112 configure a read/write circuit for performing data read and write of the memory cell array 111.

Data transfer between an external input/output port I/O and the sense amplifier 112 is performed by the input/output buffer 115 and the data line 114. That is, page data read into the sense amplifier 112 is outputted to the data line 114 to be outputted to the input/output port I/O via the input/output buffer 115. Moreover, write data supplied from the input/output port I/O is loaded into the sense amplifier 112 via the input/output buffer 115.

Address data Add supplied from the input/output port I/O is supplied to the row decoder 113 and the column decoder 118 via the address register 117. Command data Com supplied from the input/output port I/O is decoded to be set in the control signal generating circuit 116.

Each of external control signals, namely a chip enable signal /CE, an address latch enable signal ALE, a command latch enable signal CLE, a write enable signal /WE, and a read enable signal /RE are supplied to the control signal generating circuit 116. The control signal generating circuit 116, as well as performing operation control of memory operation generally based on the command Com and the external control signals, controls the internal voltage generating circuit 119 to generate various kinds of internal voltages required for data read, write, and erase.

In addition, the control signal generating circuit 116 is applied with a reference voltage from the reference voltage generating circuit 120. The control signal generating circuit 116 performs write from a selected memory cell MC on a source line SL side and controls a read operation.

FIGS. 1C and 1D show schematic cross-sectional structures of the memory cell MC and the select transistors SG1 and SG2. An n type source and drain diffusion layer 15 is formed in a p type well 2 formed on a semiconductor substrate not illustrated. A region of the p type well 2 sandwiched by two diffusion layers 15 functions as a channel region of a MOSFET configuring the memory cell MC.

Moreover, a floating gate (FG) 11 is formed on the p type well 2 via a gate insulating film 10. The floating gate 11 is configured capable of holding a charge therein, and a threshold voltage of the memory cell MC is determined by an amount of that charge. Note that a charge trap film may be employed as a charge accumulation film instead of a floating gate. A control gate (CG) 13 is formed on this floating gate 11 via an inter-gate insulating film 12.

The select transistors SG1 and SG2 comprise the p type well 2 formed on the semiconductor substrate not illustrated and the n type source and drain diffusion layer 15 formed in a surface of this p type well 2. Note that a source and drain using a fringe electric field may be employed instead of a diffusion layer. A control gate 11′ is formed on the p type well 2 via the gate insulating film 10.

FIG. 1E shows a schematic cross-sectional view of one NAND cell unit NU in the memory cell array 111. In this example, one NAND cell unit NU is configured having 64 memory cells MC having the configuration shown in FIG. 1C and the select transistors SG1 and SG2 having the configuration shown in FIG. 1D, connected in series.

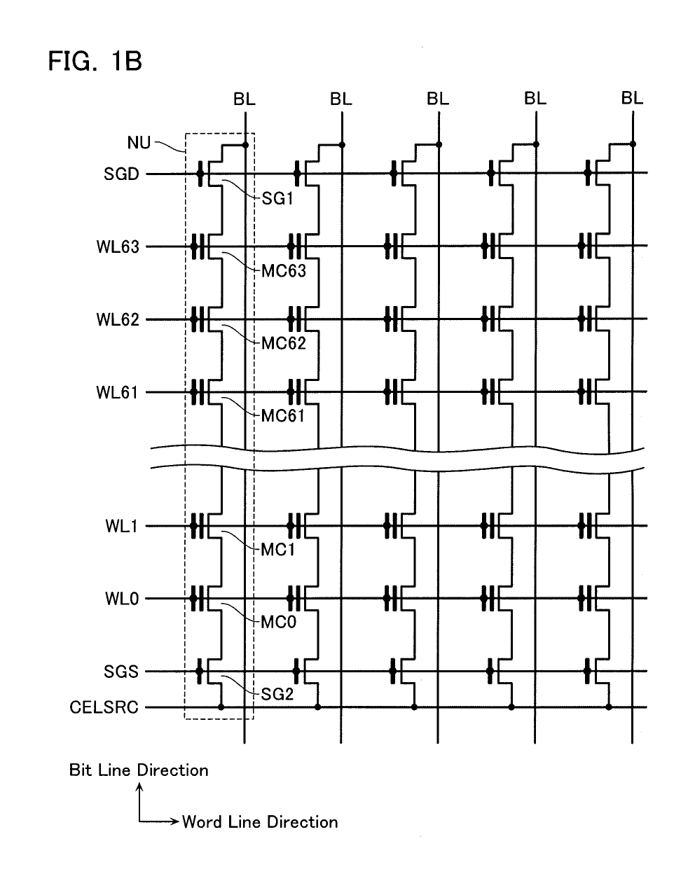

Next, a multi-level storage system in the NAND type flash memory configured in this way will be described with reference to FIGS. 2-4. As shown in FIG. 2, in the NAND type flash memory, a value of a threshold voltage in one memory cell is controlled to, for example, four types, thereby enabling two bits of data to be stored in one memory cell MC. Below, a four-level data storage system will be described as an example. Even when a multi-level data storage system other than the four-level data storage system such as for eight-level data (three bits) or more is adopted, only the number of threshold voltage distributions differs, and the basic principle is similar to the case of two-level data storage system.

In order to store two bits of data in one memory cell, four kinds of threshold voltage distributions (E and A-C) are provided corresponding to four types of data “11”, “01”, “10”, and “00”, whereby write and read of data is performed. That is, each of the four types of threshold voltage distributions (E and A-C) is allocated with one of the four types of bit information (11, 01, 10, and 00). Two sub-pages are formed corresponding to these two bits of data, that is, the upper page UPPER and the lower page LOWER.

During a read operation of these four types of data, a selected word line WL connected to the memory cell MC is applied with a read voltage, whereby conduction/non-conduction of the memory cell MC is detected to perform the read operation. A voltage value of the read voltage applied to the selected word line WL may be set to voltages VA, VB, and VC (three types) between an upper limit and a lower limit of each of the threshold voltage distributions as shown in FIG. 2, corresponding to the four types of threshold voltage distributions of the memory cell (refer to FIG. 2). The read voltage VA is the lowest voltage, with the voltage value increasing in an order of VB and VC. Note that a voltage Vread applied to an unselected memory cell MC during the read operation is assumed to be a voltage which is larger than an upper limit value of the threshold voltage distribution C allocated with data “10”. That is, the voltage Vread is a voltage applied to an unselected memory cell in a NAND cell when performing read of data, and makes the unselected memory cell conductive regardless of data held in the unselected memory cell.

In FIG. 2, voltages VAV, VBV, and VCV indicate verify voltages applied to confirm whether write has been completed when performing write to each of the threshold voltage distributions.

Furthermore, Vev is an erase verify voltage applied to the memory cell when erasing data of the memory cell, to confirm whether erase of the memory cell has been completed or not, and has a negative value. A magnitude of Vev is determined in view of an effect of interference of an adjacent memory cell. A magnitude relationship of each of the above-mentioned voltages is Vev<VA<VAV<VB<VBV<VC<VCV<Vread. Note that although the erase verify voltage Vev has a negative value as previously mentioned, a voltage actually applied to the control gate of the memory cell MC in an erase verify operation is not a negative value, but zero or a positive value. That is, in the actual erase verify operation, a back gate of the memory cell MC is provided with a positive voltage, and the control gate of the memory cell MC is applied with zero or a voltage having a positive value smaller than the back gate voltage.

The threshold voltage distribution E of the memory cell after block erase has an upper limit value also having a negative value, and is allocated with data “11”. In addition, memory cells with a write state of data “01”, “10”, and “00” have positive threshold voltage distributions A, B, and C, respectively (lower limit values of A, B, and C also have positive values). The threshold voltage distribution A of data “01” has a voltage value which is lowest, the threshold voltage distribution C of data “00” has a voltage value which is highest, and the threshold voltage distribution B of data “10” has a voltage value which is intermediate between those of data “01” and data “00”. Note that the threshold voltage distributions shown in FIG. 2 are merely one example. For example, FIG. 2 was described assuming that the threshold voltage distributions A, B, and C are all positive threshold voltage distributions, but it is also possible for the threshold voltage distribution A to be a negative voltage distribution and for the threshold voltage distributions B and C to be positive voltage distributions. Moreover, the threshold voltage distribution E may be a positive voltage distribution.

The two bit data of one memory cell is configured from lower page data and upper page data, and the lower page data and the upper page data are written to the memory cell by separate write operations, in other words, by two times of write operations. When notation data “*@” is used, * indicates the upper page data and @ indicates the lower page data.

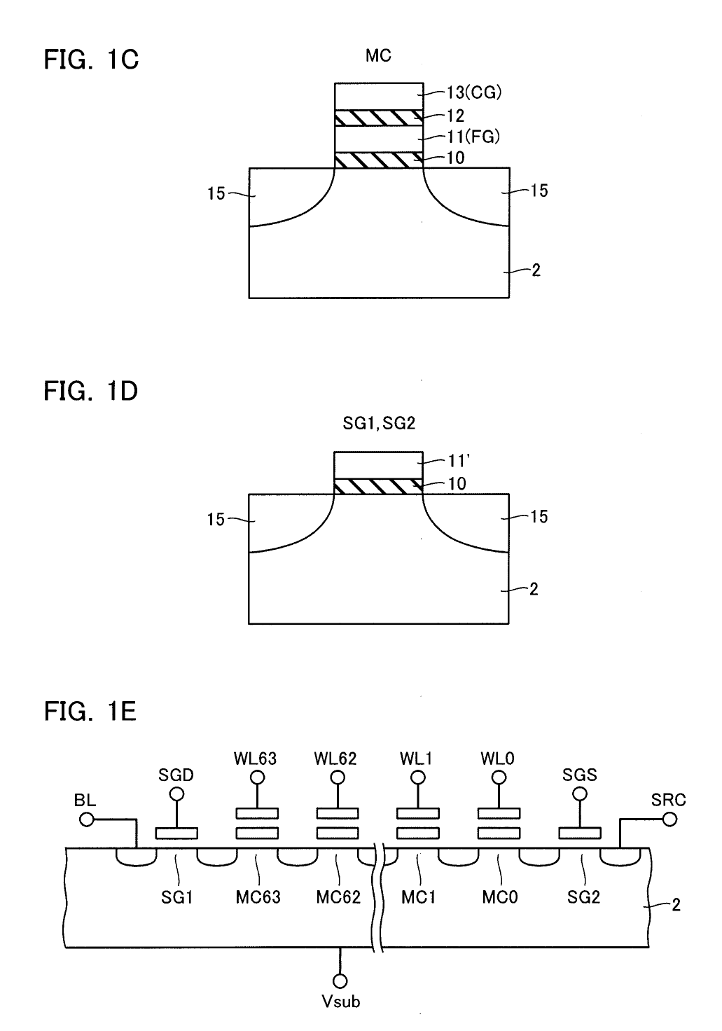

First, write of the lower page data is described with reference to FIG. 3. All of the memory cells are assumed to have the erase state threshold voltage distribution E and be storing data “11”. As shown in FIG. 3, when performing write of the lower page data, the threshold voltage distribution E of the memory cell is divided into two threshold voltage distributions (E and B′) according to a value (“1” or “0”) of the lower page data. That is, when the value of the lower page data is “1”, the erase state threshold voltage distribution E is maintained.

On the other hand, when the value of the lower page data is “0”, a tunnel oxide film of the memory cell is applied with a high electric field to inject electrons into a floating gate electrode of the memory cell, whereby a threshold voltage Vth of the memory cell is raised by a certain amount. Specifically, a verify potential VBV′ is set, and the write operation is repeated until a threshold voltage of this verify voltage VBV′ or more is attained. As a result, the memory cell changes to a write state (data “10”).

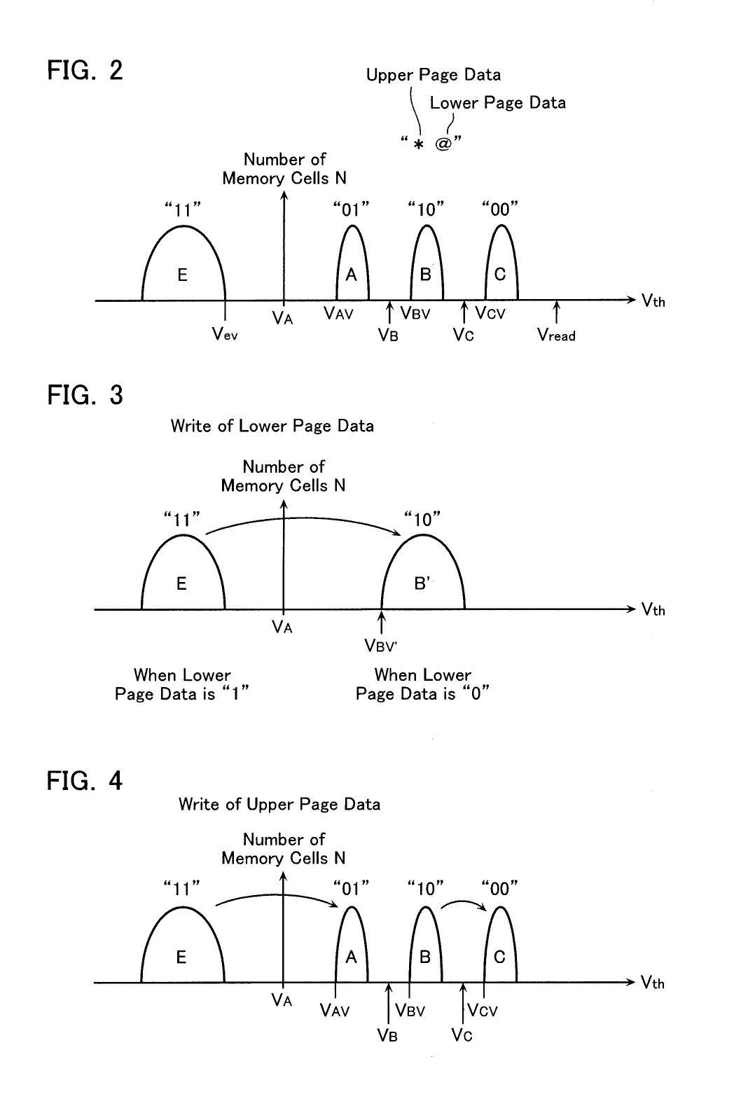

Next, write of the upper page data is described with reference to FIG. 4. Write of the upper page data is performed based on write data (the upper page data) inputted from outside of a chip and the lower page data already written to the memory cell.

That is, as shown in FIG. 4, when a value of the upper page data is “1”, a high electric field is prevented from being applied to the tunnel oxide film of the memory cell, thereby preventing a rise in the threshold voltage Vth of the memory cell. As a result, the memory cell of data “11” (erase state threshold voltage distribution E) maintains data “11” unchanged, and the memory cell of data “10” (threshold voltage distribution B′) maintains data “10” unchanged. However, the regular verify voltage VBV which is larger than the above-mentioned verify voltage VBV′ is employed to adjust the lower limit value of the threshold voltage distribution, thereby forming the threshold voltage distribution B having a width of the threshold voltage distribution narrowed.

On the other hand, when the value of the upper page data is “0”, the tunnel oxide film of the memory cell is applied with a high electric field to inject electrons into the floating gate electrode of the memory cell, whereby the threshold voltage Vth of the memory cell is raised by a certain amount. As a result, the memory cell of data “11” (erase state threshold voltage distribution E) changes to data “01” of the threshold voltage distribution A, and the memory cell of data “10” changes to data “00” of the threshold voltage distribution C. At this time, the verify voltages VAV and VCV are employed to adjust the lower limit values of the threshold voltage distributions A and C.

The above is one example of a data write system in a general four-level storage system. This is merely one example, and various methods other than the above may be adopted for allocation of data to the threshold voltage distributions, a procedure of the write operation, and so on. Moreover, even in a multi-bit storage system of three bits or more, it is only required to add to the above-described operations an operation that divides the threshold voltage distribution into eight types according to a further higher level of page data, and the basic principle is similar to the above.

In the case of a memory cell MC having the four threshold voltage distributions of FIG. 2, the read operation is executed by sequentially applying the voltages VA, VB, and VC. For example, when these voltages are applied in an order of VA→VB→VC, the threshold voltage of a memory cell MC which is conductive at the voltage VA is determined to be the threshold voltage distribution E. In subsequently executed read operations applying the voltages VB and VC, passing a current through a memory cell that has been determined to have the threshold voltage distribution E results in an unnecessary increase in power consumption and is therefore undesirable. Conventionally, there exists also a technology aiming to reduce the current by forcibly connecting the bit line BL connected to such a memory cell to a source line, and so on. However, in such a technology, there is a problem that a high-voltage transistor of large area becomes required, hence occupied area of the semiconductor memory device increases.

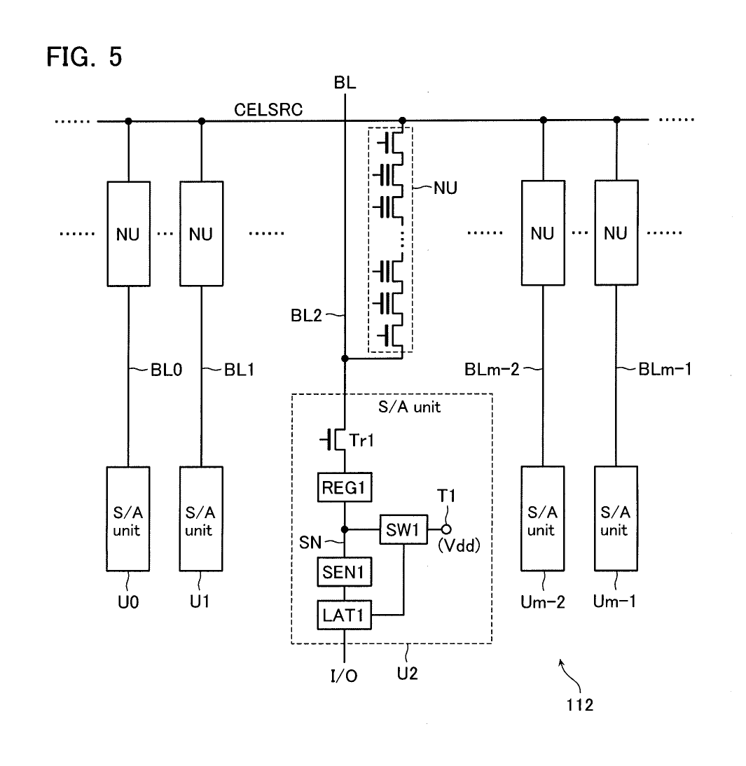

Therefore, the sense amplifier circuit 112 in the first embodiment has a structure as shown in FIG. 5. This sense amplifier circuit 112 of the first embodiment comprises a plurality of sense units U0˜Um−1. Each of the plurality of sense units U0˜Um−1 is connected to one NAND cell unit NU.

One sense unit U respectively comprises a high-voltage transistor Tr1, a regulator REG1, a first switch circuit SW1, a sense amplifier SENT, and a latch circuit LAT1.

The high-voltage transistor Tr1 is connected between the bit line BL and the regulator REG1. The regulator REG1 is a circuit for regulating a power supply voltage Vdd supplied from a power supply voltage terminal T1. The sense amplifier SENT is connected to a sense node SN that is connected to the bit line BL via the high-voltage transistor Tr1 and the regulator REG1. The sense amplifier SEN1 detects and amplifies a potential of the bit line BL. The latch circuit LAT1 latches a signal amplified by the sense amplifier SEN1.

The first switch circuit SW1 is connected between the power supply voltage terminal T1 and the regulator REG1 (sense node SN). The first switch circuit SW1 is set to a conductive state in the read operation, but switches from a conductive state to a non-conductive state according to held data of the latch circuit LAT1. When the first switch circuit SW1 attains a non-conductive state, supply of a voltage from the power supply voltage terminal T1 to the bit line BL is stopped. Moreover, a charge of the bit line BL is discharged toward the source line CELSRC via the NAND cell unit NU only.

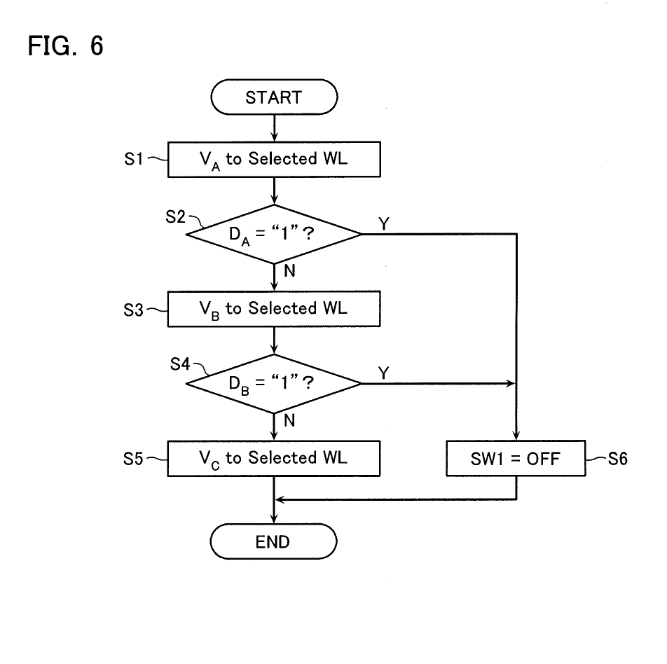

Next, a procedure of the read operation in the present embodiment will be described with reference to the flowchart of FIG. 6. Described here is the case where the read operation is executed on the plurality of memory cells MC (two bits of data are held in one memory cell) connected to the selected word line WL (selected word line).

In this case, the selected word line WL is first applied with one voltage, for example, the voltage VA (S1). Note that similarly to in a conventional read operation, an unselected word line WL is applied with the voltage Vread, and the bit line BL is charged to the power supply voltage Vdd via the first switch circuit SW1. Then, as a result of the select transistor SG1 or SG2 being conductive, the read operation employing the voltage VA is started.

This read operation causes a signal of the bit line BL0 to be detected and amplified by the sense amplifier SEN1, and data according with that detection/amplification to be held in the latch circuit LAT1. If data held in any latch circuit LAT1 is “1”, there is no need to repeat the read operation from a corresponding memory cell MC. Therefore, the first switch circuit SW1 in the sense unit U corresponding to that memory cell MC is switched from a conductive state to a non-conductive state (S6). On the other hand, regarding a memory cell MC whose data read and held in the latch circuit LAT1 as a result of the read operation is “0”, the first switch SW1 is held unchanged in a conductive state, and the procedure shifts to Step S3.

In step S3, the selected word line WL is applied with, for example, the voltage VB. Similarly to in step S1, the unselected word line WL is applied with the voltage Vread, and the bit line BL is charged to the power supply voltage Vdd via the first switch circuit SW1. Then, as a result of the select transistor SG1 or SG2 being conductive, the read operation employing the voltage VB is started.

This read operation causes a signal of the bit line BL0 to be detected and amplified by the sense amplifier SEN1, and data according with that detection/amplification to be held in the latch circuit LAT1. If data held in any latch circuit LAT1 is “1”, the first switch circuit SW1 in the sense unit U corresponding to that memory cell MC is switched from a conductive state to a non-conductive state (S6). This results in supply of the power supply voltage Vdd to the NAND cell unit in which such memory cell MC is included being stopped thereafter.

On the other hand, regarding a memory cell MC whose data read and held in the latch circuit LAT1 as a result of the read operation is “0”, the first switch SW1 is held unchanged in a conductive state, and the procedure shifts to step S5.

In step S5, the selected word line WL is applied with, for example, the voltage VC. Similarly to in step S1, the unselected word line WL is applied with the voltage Vread, and the bit line BL is charged to the power supply voltage Vdd via the first switch circuit SW1. Then, as a result of the select transistor SG1 or SG2 being conductive, the read operation employing the voltage VC is started.

A result of the read operation in the above steps S1, S3, and S5 is held in the latch circuit LAT1, hence it is determined which of the threshold voltage distributions E, A, B, and C the memory cell MC has, according to this latch data. Thereby, the read operation finishes.

As described above, in the nonvolatile semiconductor memory device of the present embodiment, in the case of performing a plurality of times of the read operations (S1, S3, and S5), when held data has been decisively read by a mid-way read operation, the first switch circuit SW1 is switched from a conductive state to a non-conductive state. As a result, wasted current can be prevented from being supplied to a memory cell where held data has been decisively read, and power consumption can be lowered. Moreover, forcibly connecting the bit line BL to a ground potential or the like is also not required, and a transistor for doing so is not required, hence an increase in occupied area of the semiconductor memory device can be suppressed.

### Second Embodiment

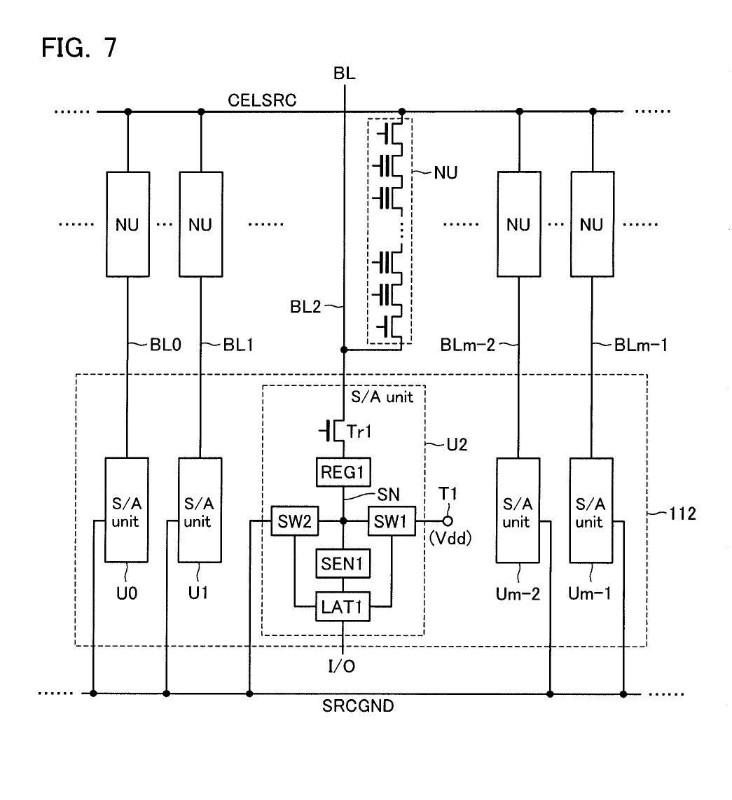

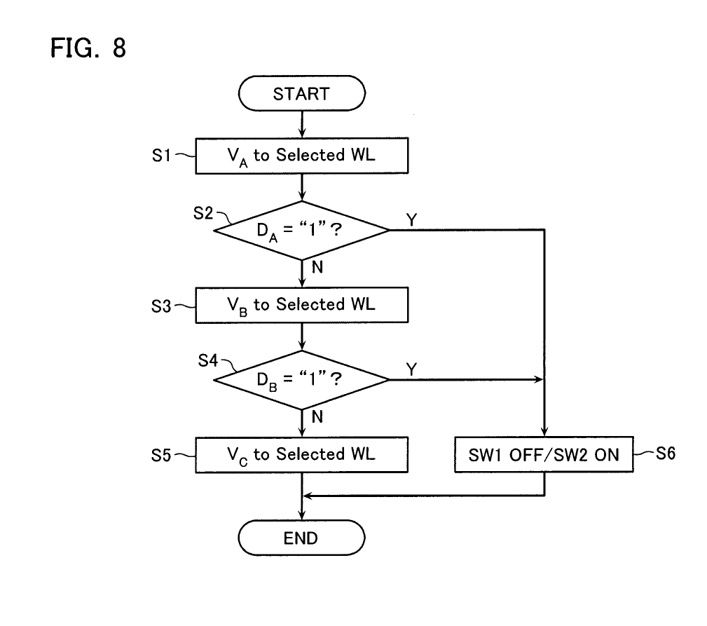

Next, a nonvolatile semiconductor memory device according to a second embodiment will be described with reference to FIGS. 7 and 8. An overall configuration of this semiconductor device of the second embodiment is similar to that shown in FIG. 1A. However, this embodiment has a different configuration of the sense amplifier circuit 112 from that of the first embodiment.

A configuration of the sense amplifier circuit 112 in the nonvolatile semiconductor memory device of this second embodiment will be described below with reference to FIG. 7. Configurative elements identical to those in FIG. 5 are assigned with identical reference symbols to those assigned in FIG. 5, and a detailed description of such configurative elements is omitted below. The sense amplifier circuit 112 of this embodiment comprises a second switch circuit SW2 in addition to the configurative elements of the sense amplifier circuit 112 of the first embodiment. This second switch circuit SW2 is connected between a source ground line SRCGND and the bit line BL. The source ground line SRCGND is a global line disposed in a direction intersecting the bit lines in order to short-circuit those bit lines. Moreover, this second switch circuit SW2 is set to a non-conductive state in the read operation, but switches from a non-conductive state to a conductive state according to held data of the latch circuit LAT1. As a result of the second switch circuit SW2 attaining a conductive state and the bit line BL and the source ground line SRCGND consequently being short-circuited, discharging of the bit line BL is promoted.

Next, a procedure of the read operation in the second embodiment will be described with reference to the flowchart of FIG. 8. Described here is the case where, similarly to in the first embodiment, the read operation is executed on the plurality of memory cells MC (two bits of data are held in one memory cell) connected to the selected word line WL (selected word line).

The procedure of FIG. 8 is substantially similar to the procedure of FIG. 6. However, in step S6, in addition to the first switch circuit SW1 switching from a conductive state to a non-conductive state, the second switch circuit SW2 switches from a non-conductive state to a conductive state (the bit line BL and the source ground line SRCGND are short-circuited). The second switch circuit SW2 being conductive causes discharging of the bit line BL to be promoted, thereby enabling charge of a bit line BL where held data has been decisively read to be promptly discharged. Moreover, the bit line BL where the read operation has finished being connected to the source ground line SRCGND and thereby fixed to a ground potential removes the need for the bit line to be placed in a floating state. This makes it possible to reduce an effect on another bit line where the read operation has not finished.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the above embodiments described the case of repeatedly executing the read operation on one memory cell MC in the case where two bits of data are written to one memory cell MC. However, the present invention is not limited to this case and may also be applied to the case where, for some reason, the read operation is repeatedly performed on one memory cell MC. Moreover, the present invention may be applied not only to an ordinary read operation, but also to a verify read operation after a write operation or an erase verify read operation after an erase operation.

What is claimed is:

1. A nonvolatile semiconductor memory device, comprising:
a memory cell array configured having a plurality of NAND cell units arranged therein, each of the NAND cell units being configured having a plurality of memory cells connected in series therein;
a bit line connected to one end of the NAND cell unit;
a source line connected to the other end of the NAND cell unit; and
a sense amplifier circuit connected to the bit line,
the sense amplifier circuit comprising:
a first switch circuit connected between a power supply voltage terminal and a sense node;
a sense amplifier connected to the sense node; and
a latch circuit that latches a signal outputted from the sense amplifier, and
the first switch circuit being configured to switch to a non-conductive state according to data latched by the latch circuit.

2. The nonvolatile semiconductor memory device according to claim 1, wherein
after the first switch circuit has switched to a non-conductive state, the bit line is discharged to the source line via the NAND cell unit only.

3. The nonvolatile semiconductor memory device according to claim 1, wherein
the sense amplifier circuit further comprises:
a regulator that functions to regulate a voltage supplied by the power supply voltage terminal; and
a transistor connected between the regulator and the bit line.

4. The nonvolatile semiconductor memory device according to claim 1, wherein
the memory cell is configured capable of holding two or more bits of data and, during a read operation, a control gate of the memory cell is sequentially applied with a plurality of types of read voltages, and
the latch circuit is configured to, each time one of the plurality of types of read voltages is applied, hold data read from the sense amplifier circuit.

5. The nonvolatile semiconductor memory device according to claim 1, further comprising:
a second switch circuit connected between a global line and the sense node, wherein
the second switch circuit is configured to switch from a non-conductive state to a conductive state according to data latched by the latch circuit.

6. The nonvolatile semiconductor memory device according to claim 5, wherein
the sense amplifier circuit further comprises:
a regulator that functions to regulate a voltage supplied by the power supply voltage terminal; and
a transistor connected between the regulator and the bit line.

7. The nonvolatile semiconductor memory device according to claim 5, wherein
the memory cell is configured capable of holding two or more bits of data and, during a read operation, a control gate of the memory cell is sequentially applied with a plurality of types of read voltages, and
the latch circuit is configured to, each time one of the plurality of types of read voltages is applied, hold data read from the sense amplifier circuit.

8. The nonvolatile semiconductor memory device according to claim 5, wherein
the global line is a source ground line arranged in a direction intersecting a plurality of the bit lines in order to short-circuit the plurality of the bit lines.

9. A read method of a nonvolatile semiconductor memory device, the nonvolatile semiconductor memory device comprising: a memory cell array configured having a plurality of NAND cell units arranged therein, each of the NAND cell units being configured having a plurality of memory cells connected in series therein; a bit line connected to one end of the NAND cell unit; a source line connected to the other end of the NAND cell unit; and
a sense amplifier circuit connected to the bit line, the read method comprising:
latching data read from the memory cell included in the NAND cell unit, in the latch circuit;
stopping supply of a voltage to the bit line according to latch data of the latch circuit.

10. The read method of a nonvolatile semiconductor memory device according to claim 9, wherein
supply of the voltage to the bit line is performed by switching a first switch to a non-conductive state, the first switch be ing connected to a power supply voltage terminal supplying the voltage.

11. The read method of a nonvolatile semiconductor memory device according to claim 9, further comprising:
short-circuiting between the bit line and a global line according to latch data of the latch circuit.

12. The read method of a nonvolatile semiconductor memory device according to claim 11, wherein
short-circuiting between the bit line and the global line is performed by switching a second switch to a conductive state, the second switch being electrically connected between the global line and the bit line.
